(19) United States
(12) Patent Application Publication
(10) Pub. No.: US 2026/0051868 A1
(43) Pub. Date: Feb. 19, 2026

(54) PIEZOELECTRIC DEVICE WITH CONDUCTIVE PROTECTIVE LAYER INTERCONNECTS

(71) Applicant: RF360 Singapore Pte. Ltd., Republic Plaza (SG)

(72) Inventors: Poh Hoong YONG, Johor Bahru (MY); Puay Hoon Christie TYU, Singapore (SG); Ren Bin YANG, Singapore (SG); Marc Konstantin DIETRICH, Munich (DE); Weiqiang LIM, Singapore (SG); Florian GOETZ, München (DE)

(21) Appl. No.: 18/809,099

(22) Filed: Aug. 19, 2024

(51) Int. Cl. H03H 9/02; H03H 3/08; H03H 9/145

(52) U.S. Cl. CPC H03H 9/02937; H03H 3/08; H03H 9/14541

(57) ABSTRACT

Aspects are disclosed for a piezoelectric device and a method of manufacturing a piezoelectric device. For example, the piezoelectric device can include a substrate, a piezoelectric layer, and an electrode formed on the substrate. The electrode includes a conductive layer and a conductive protective layer that is different from the conductive layer. The piezoelectric device can further include an interconnect formed on the piezoelectric layer over the conductive protective layer of the electrode. The interconnect provides an electrical path from the electrode to the piezoelectric layer.

### TECHNICAL FIELD

This disclosure relates generally to wireless devices. For example, aspects of the present disclosure relate to piezoelectric devices with conductive protective layer interconnects.

### BACKGROUND

Electronic devices use radio-frequency (RF) signals to communicate information. These radio-frequency signals enable users to talk with friends, download information, share pictures, remotely control household devices, and receive global positioning information. To transmit or receive the radio-frequency signals within a given frequency band, the electronic device may use filters to pass signals within the frequency band and to suppress (e.g., attenuate) jammers or noise having frequencies outside of the frequency band. It can be challenging, however, to design a filter that provides filtering for high-frequency applications, including those that utilize frequencies above 2 gigahertz (GHz), while preventing or reducing spurious modes within a passband of the filter.

### SUMMARY

Aspects of the present disclosure relate to piezoelectric devices with conductive protective layer interconnects. In some aspects, a piezoelectric device is provided. The piezoelectric device includes: a substrate; a piezoelectric layer; an electrode formed on the substrate, the electrode including a conductive layer and a conductive protective layer that is different from the conductive layer; and an interconnect formed on the piezoelectric layer over the conductive protective layer of the electrode, the interconnect providing an electrical path from the electrode to the piezoelectric layer.

In some aspects, a method of manufacturing a piezoelectric device is provided. The method includes: forming an electrode layer for a piezoelectric device disposed on a substrate; forming a conductive protective layer on the electrode layer; forming an interconnect for the piezoelectric device on the conductive protective layer; and forming an electrode for the piezoelectric device, wherein the interconnect forms an electrical path from an exposed surface of the conductive protective layer to the piezoelectric device.

In some aspects, one or more of the piezoelectric devices described herein can be part of a computing device, such as a mobile device (e.g., a mobile telephone or so-called “smart phone”, a tablet computer, or other type of mobile device), a wearable device, an extended reality device (e.g., a virtual reality (VR) device, an augmented reality (AR) device, or a mixed reality (MR) device), a personal computer, a laptop computer, a video server, a television (e.g., a network-connected television), a vehicle (or a computing device of a vehicle), or other device. In some aspects, the computing device can include at least one camera for capturing one or more images or video frames. For example, the computing device can a camera (e.g., an RGB camera) or multiple cameras for capturing one or more images and/or one or more videos including video frames. In some aspects, the computing device can at least one display for displaying one or more images, videos, notifications, or other displayable data. In some aspects, the computing device can at least one transmitter configured to transmit information, data, etc. over a transmission medium to at least one device. In some aspects, the computing device can include at least one process. The at least one processor includes a central processing unit (CPU), a graphics processing unit (GPU), a digital signal processor (DSP), a neural processing unit (NPU), a neural signal processor (NSP), any combination thereof, and/or other processing device or component.

This summary is not intended to identify key or essential features of the claimed subject matter, nor is it intended to be used in isolation to determine the scope of the claimed subject matter. The subject matter should be understood by reference to appropriate portions of the entire specification of this patent, any or all drawings, and each claim.

The foregoing, together with other features and embodiments, will become more apparent upon referring to the following specification, claims, and accompanying drawings.

### BRIEF DESCRIPTION OF DRAWINGS

FIG. 1 illustrates an example operating environment for an acoustic filter with geometry tuning in accordance with aspects described herein.

FIG. 2 illustrates an example wireless transceiver including surface-acoustic-wave filters with geometry tuning in accordance with aspects described herein.

FIG. 3A illustrates an example implementation of a surface-acoustic-wave filter that can be implemented with geometry tuning in accordance with aspects described herein.

FIG. 3B illustrates an example implementation of a high-quality temperature-compensated surface-acoustic-wave filter with geometry tuning in accordance with aspects described herein.

FIG. 3C illustrates an example implementation of a surface-acoustic-wave filter that can be implemented with geometry tuning in accordance with aspects described herein.

FIG. 3D illustrates an example implementation of a surface-acoustic-wave filter that can be implemented with geometry tuning in accordance with aspects described herein.

FIG. 4 illustrates an example graph depicting velocity and mode profiles associated with regions of a surface-acoustic-wave filter with site-selective piezoelectric-layer trimming.

FIG. 5A illustrates aspects of a piezoelectric device with geometry tuning in accordance with aspects described herein.

FIG. 5B illustrates aspects of a piezoelectric device with geometry tuning in accordance with aspects described herein.

FIGS. 6A-6F illustrate a process of manufacturing a piezoelectric device based on etching between an interconnect and an electrode.

FIGS. 7A-7F illustrate a process of manufacturing a piezoelectric device in accordance with some aspects of the disclosure.

FIG. 8 is a flow diagram illustrating an example process for manufacturing a surface-acoustic-wave filter using geometry tuning in accordance with aspects described herein.

### DETAILED DESCRIPTION

Certain aspects of this disclosure are provided below for illustration purposes. Alternate aspects may be devised without departing from the scope of the disclosure. Additionally, well-known elements of the disclosure will not be described in detail or will be omitted so as not to obscure the relevant details of the disclosure. Some of the aspects described herein can be applied independently and some of them may be applied in combination as would be apparent to those of skill in the art. In the following description, for the purposes of explanation, specific details are set forth in order to provide a thorough understanding of aspects of the application. However, it will be apparent that various aspects may be practiced without these specific details. The figures and description are not intended to be restrictive.

The ensuing description provides example aspects only, and is not intended to limit the scope, applicability, or configuration of the disclosure. Rather, the ensuing description of the example aspects will provide those skilled in the art with an enabling description for implementing an example aspect. It should be understood that various changes may be made in the function and arrangement of elements without departing from the spirit and scope of the application as set forth in the appended claims.

The terms “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

To transmit or receive radio-frequency signals within a given frequency band, an electronic device may use filters to pass signals within the frequency band and to suppress (e.g., attenuate) jammers or noise having frequencies outside of the frequency band. Electroacoustic devices (e.g., “acoustic filters”) can be used to filter high-frequency signals in many applications, such as those with frequencies that are greater than 100 megahertz (MHz). An acoustic filter is tuned to pass certain frequencies (e.g., frequencies within its passband) and attenuate other frequencies (e.g., frequencies that are outside of its passband). Using a piezoelectric material as a vibrating medium, the acoustic filter operates by transforming an electrical signal wave that is propagating along an electrical conductor into an acoustic wave (e.g., an acoustic signal wave) that forms across the piezoelectric material. The acoustic wave is then converted back into an electrical filtered signal. The acoustic filter can include an electrode structure that transforms or converts between the electrical and acoustic waves.

The acoustic wave propagates across the piezoelectric material at a velocity having a magnitude that is significantly less than that of the propagation velocity of the electrical wave. Generally, the magnitude of the propagation velocity of a wave is proportional to a size of a wavelength of the wave. Consequently, after conversion of the electrical signal wave into the acoustic wave, the wavelength of the acoustic wave is significantly smaller than the wavelength of the electrical signal wave. The resulting smaller wavelength of the acoustic wave enables filtering to be performed using a smaller filter device. This permits acoustic filters to be used in space-constrained devices, including portable electronic devices such as cellular phones.

Design of acoustic filters, including those that utilize frequencies above 2 gigahertz (GHz), that can provide filtering for high-frequency applications while maintaining target performance levels can involve trade-offs and challenges. For example, such devices are fabricated on a wafer that can contain thousands or tens of thousands of electroacoustic resonators per wafer. Production tolerances during fabrication of such a wafer can result in performance variations across the wafer. On

Piezoelectric devices (e.g., a filter, such as a surface acoustic wave (SAW) filter) can be designed with an electrode that is coupled to an interconnect that forms an electrical path to the piezoelectric device. Generally, an electrode of a piezoelectric device is an aluminum (Al)-based electrode with one or more interconnects formed with aluminum or copper (Cu). Aluminum is highly reactive due to its high tendency to lose electrons and form positive ions (Al³⁺) based on a relatively low ionization energy. Copper is less reactive than aluminum but can still oxidize under the right conditions. Copper has a moderate ionization energy and can lose electrons to form positive ions (Cu⁺ or Cu²⁺) when reacting with oxygen.

During manufacturing of a piezoelectric device with an aluminum or copper electrode, there is a risk of oxidation at the surface. Such oxidation needs to be removed (e.g., by etching away the oxidation) before an interconnect is formed on the aluminum or copper electrode. Conventionally, an etching process is used to strip the oxide layer from the electrode, which is followed by a timed construction of the interconnect over the aluminum electrode. The timed etching process is subject to variations that cannot be easily controlled. For example, the surface roughness of the etching process creates a surface roughness that cannot be easily controlled and increases ohmic contact losses, which in turn increases yield loss of piezoelectric device manufacturing.

According to aspects described herein, a piezoelectric device (e.g., a filter, such as a SAW filter) can be formed by applying a conductive protective layer (also referred to as a barrier layer) to an electrode (e.g., an aluminum electrode) to prevent oxidation. The electrode can be coupled to an interconnect that forms an electrical path to the piezoelectric device.

In some cases, the conductive protective layer is a different material than a conventional electrode. The conductive protective layer can include a stable oxide layer that improves interconnection performance and reduces process variation. The thickness of the conductive protective layer can be configured to prevent electrical parasitics (e.g., ohmic, capacitive, or inductive parasitics) from influencing electrical performance. The thickness of the conductive protective layer can also be configured to minimize the influence of electro-acoustical properties of a piezoelectric layer. In some examples, the conductive protective layer be a smoother surface and provide a consistent interface for an interconnect of the piezoelectric device to reduce scattering and absorption losses. Improving the bonding between devices based on a consistent interface also improves yield and reduces performance variation without affecting electrical performance and the frequency trimming process.

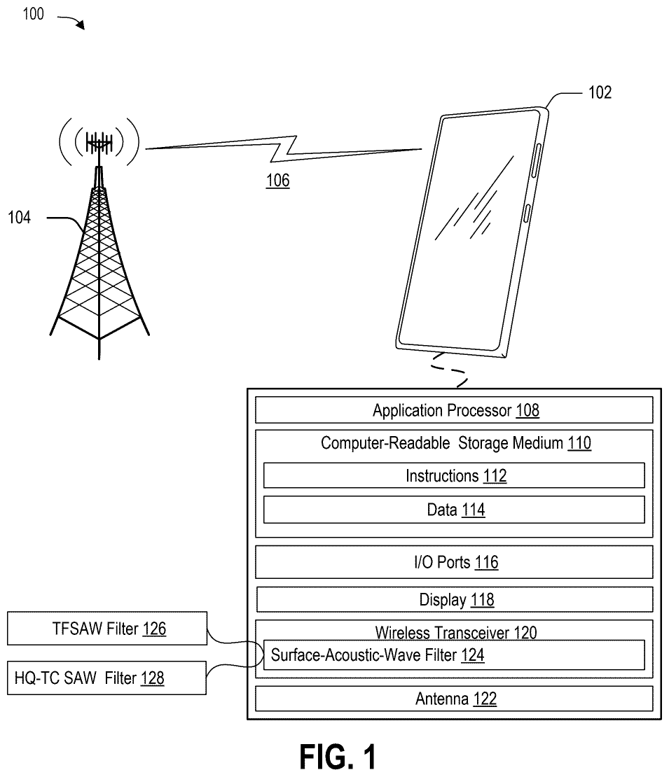

FIG. 1 illustrates an example environment 100 for a piezoelectric device that can be tuned in accordance with aspects described herein. In the environment 100, a computing device 102 communicates with a base station 104 through a wireless communication link 106 (e.g., a wireless link). In this example, the computing device 102 is depicted as a smartphone. However, the computing device 102 can be implemented as any suitable computing or electronic device, such as a modem, a cellular base station, a broadband router, an access point, a cellular phone, a gaming device, a navigation device, a media device, a laptop computer, a desktop computer, a tablet computer, a wearable computer, a server, a network-attached storage (NAS) device, a smart appliance or other internet of things (IoT) device, a medical device, a vehicle-based communication system, a radar, a radio apparatus, and so forth.

The base station 104 communicates with the computing device 102 via the wireless communication link 106, which can be implemented as any suitable type of wireless link. Although depicted as a tower of a cellular network, the base station 104 can represent or be implemented as another device, such as a satellite, a server device, a terrestrial television broadcast tower, an access point, a peer-to-peer device, a mesh network node, and so forth. Therefore, the computing device 102 may communicate with the base station 104 or another device via a wireless connection.

The wireless communication link 106 can include a downlink of data or control information communicated from the base station 104 to the computing device 102, an uplink of other data or control information communicated from the computing device 102 to the base station 104, or both a downlink and an uplink. The wireless communication link 106 can be implemented using any suitable communication protocol or standard, such as 2nd-generation (2G), 3rd-generation (3G), 4th-generation (4G), or 5th-generation (5G) cellular; IEEE 802.11 (e.g., Wi-Fi®); IEEE 802.15 (e.g., Bluetooth®); IEEE 802.16 (e.g., WiMAX®); and so forth. In some implementations, the wireless communication link 106 may wirelessly provide power and the base station 104 or the computing device 102 may comprise a power source.

As shown, the computing device 102 includes an application processor 108 and a computer readable storage medium (CRM) 110. The application processor 108 can include any type of processor, such as a multi-core processor, which executes processor-executable code stored by the CRM 110. The CRM 110 can include any suitable type of data storage media, such as volatile memory (e.g., random access memory (RAM)), non-volatile memory (e.g., Flash memory), optical media, magnetic media (e.g., disk), and so forth. In the context of this disclosure, the CRM 110 is implemented to store instructions 112, data 114, and other information of the computing device 102, and thus does not include transitory propagating signals or carrier waves.

The computing device 102 can also include input/output ports 116 (I/O ports 116) and a display 118. The I/O ports 116 enable data exchanges or interaction with other devices, networks, or users. The I/O ports 116 can include serial ports (e.g., universal serial bus (USB) ports), parallel ports, audio ports, infrared (IR) ports, user interface ports such as a touchscreen, and so forth. The display 118 presents graphics of the computing device 102, such as a user interface associated with an operating system, program, or application. Alternatively or additionally, the display 118 can be implemented as a display port or virtual interface, through which graphical content of the computing device 102 is presented.

A wireless transceiver 120 of the computing device 102 provides connectivity to respective networks and other electronic devices connected therewith. The wireless transceiver 120 can facilitate communication over any suitable type of wireless network, such as a wireless local area network (WLAN), peer-to-peer (P2P) network, mesh network, cellular network, wireless wide-area-network (WWAN), and/or wireless personal-area-network (WPAN). In the context of the example environment 100, the wireless transceiver 120 enables the computing device 102 to communicate with the base station 104 and networks connected therewith. However, the wireless transceiver 120 can also enable the computing device 102 to communicate “directly” with other devices or networks.

The wireless transceiver 120 includes circuitry and logic for transmitting and receiving communication signals via an antenna 122. Components of the wireless transceiver 120 can include amplifiers, switches, mixers, analog-to-digital converters, filters, and so forth for conditioning the communication signals (e.g., for generating or processing signals). The wireless transceiver 120 can also include logic to perform in-phase/quadrature (I/Q) operations, such as synthesis, encoding, modulation, decoding, demodulation, and so forth. In some cases, components of the wireless transceiver 120 are implemented as separate transmitter and receiver entities. Additionally or alternatively, the wireless transceiver 120 can be realized using multiple or different sections to implement respective transmitting and receiving operations (e.g., separate transmit and receive chains). In general, the wireless transceiver 120 processes data and/or signals associated with communicating data of the computing device 102 over the antenna 122.

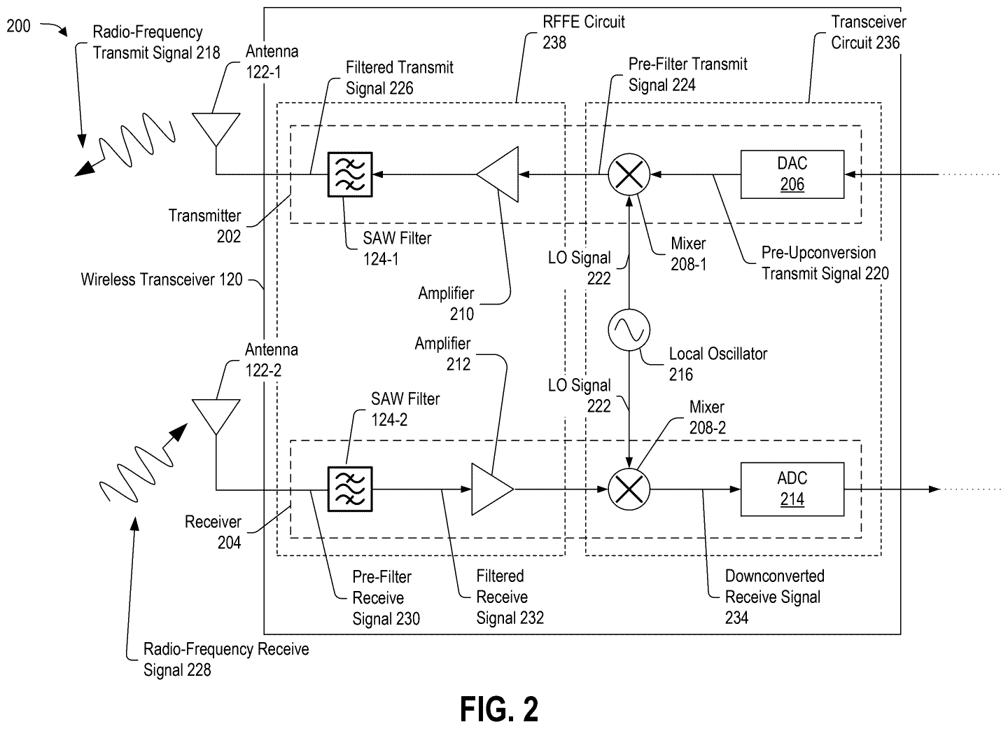

In the example shown in FIG. 1, the wireless transceiver 120 includes at least one surface-acoustic-wave filter 124 (e.g., an electroacoustic device, a surface acoustic wave (SAW) device, etc.). In some implementations, the wireless transceiver 120 includes multiple surface-acoustic-wave filters 124, which can be arranged in series, in parallel, in a ladder structure, in a lattice structure, or some combination thereof. The surface-acoustic-wave filter 124 can be a thin-film surface-acoustic-wave filter or a high-quality temperature-compensated (HQ-TC) SAW filter. The surface-acoustic-wave filter 124 can be manufactured using site-selective piezoelectric-layer trimming to suppress spurious modes. The surface-acoustic-wave filter 124 is further described with respect to FIG. 2.

FIG. 2 illustrates an example wireless transceiver 120. In the depicted configuration, the wireless transceiver 120 includes a transmitter 202 and a receiver 204, which are respectively coupled to a first antenna 122-1 and a second antenna 122-2. In other implementations, the transmitter 202 and the receiver 204 can be connected to a same antenna through a duplexer (not shown), such as a transmit-receive switch or a circulator. The transmitter 202 is shown to include at least one digital-to-analog converter (DAC) 206, at least one first mixer 208-1, at least one amplifier 210 (e.g., a power amplifier), and at least one first surface-acoustic-wave filter 124-1. The receiver 204 includes at least one second surface-acoustic-wave filter 124-2, at least one amplifier 212 (e.g., a low-noise amplifier), at least one second mixer 208-2, and at least one analog-to-digital converter (ADC) 214. The first mixer 208-1 and the second mixer 208-2 are coupled to a local oscillator 216. Although not explicitly shown, the DAC 206 of the transmitter 202 and the analog-to-digital converter 214 of the receiver 204 can be coupled to the application processor 108 (of FIG. 1) or another processor associated with the wireless transceiver 120 (e.g., a modem).

In some implementations, the wireless transceiver 120 is implemented using multiple circuits, such as a transceiver circuit 236 and a radio-frequency front-end (RFFE) circuit 238. As such, the components that form the transmitter 202 and the receiver 204 are distributed across these circuits. As shown in FIG. 2, the transceiver circuit 236 includes the DAC 206 of the transmitter 202, the mixer 208-1 of the transmitter 202, the mixer 208-2 of the receiver 204, and the analog-to-digital converter 214 of the receiver 204. In other implementations, the DAC 206 and the analog-to-digital converter 214 can be implemented on another separate circuit that includes the application processor 108 or the modem. The RFFE circuit 238 includes the amplifier 210 of the transmitter 202, the surface-acoustic-wave filter 124-1 of the transmitter 202, the surface-acoustic-wave filter 124-2 of the receiver 204, and the amplifier 212 of the receiver 204.

During transmission, the transmitter 202 generates a radio-frequency transmit signal 218, which is transmitted using the antenna 122-1. To generate the radio-frequency transmit signal 218, the DAC 206 provides a pre-upconversion transmit signal 220 to the first mixer 208-1. The pre-upconversion transmit signal 220 can be a baseband signal or an intermediate-frequency signal. The first mixer 208-1 upconverts the pre-upconversion transmit signal 220 using a local oscillator (LO) signal 222 provided by the local oscillator 216. The first mixer 208-1 generates an upconverted signal, which is referred to as a pre-filter transmit signal 224. The pre-filter transmit signal 224 can be a radio-frequency signal and include some spurious (e.g., unwanted) frequencies, such as a harmonic frequency. The amplifier 210 amplifies the pre-filter transmit signal 224 and passes the amplified pre-filter transmit signal 224 to the first surface-acoustic-wave filter 124-1.

The first surface-acoustic-wave filter 124-1 filters the amplified pre-filter transmit signal 224 to generate a filtered transmit signal 226. As part of the filtering process, the first surface-acoustic-wave filter 124-1 attenuates the one or more spurious frequencies within the pre-filter transmit signal 224. The transmitter 202 provides the filtered transmit signal 226 to the antenna 122-1 for transmission. The transmitted filtered transmit signal 226 is represented by the radio-frequency transmit signal 218.

During reception, the antenna 122-2 receives a radio-frequency receive signal 228 and passes the radio-frequency receive signal 228 to the receiver 204. The second surface-acoustic-wave filter 124-2 accepts the received radio-frequency receive signal 228, which is represented by a pre-filter receive signal 230. The second surface-acoustic-wave filter 124-2 filters any spurious frequencies within the pre-filter receive signal 230 to generate a filtered receive signal 232. In some examples, spurious frequencies can include jammers or noise from the external environment.

The amplifier 212 of the receiver 204 amplifies the filtered receive signal 232 and passes the amplified filtered receive signal 232 to the second mixer 208-2. The second mixer 208-2 downconverts the amplified filtered receive signal 232 using the LO signal 222 to generate the downconverted receive signal 234. The analog-to-digital converter 214 converts the downconverted receive signal 234 into a digital signal, which can be processed by the application processor 108 or another processor associated with the wireless transceiver 120 (e.g., the modem).

FIG. 2 illustrates one example configuration of the wireless transceiver 120. Other configurations of the wireless transceiver 120 can support multiple frequency bands and share an antenna 122 across multiple transceivers. One of ordinary skill in the art can appreciate the variety of other configurations for which surface-acoustic-wave filters 124 may be included. For example, the surface-acoustic-wave filters 124 can be integrated within duplexers or diplexers of the wireless transceiver 120. Example implementations of the surface-acoustic-wave filter 124-1 or 124-2 are further described with respect to FIGS. 3-1 and 3-2.

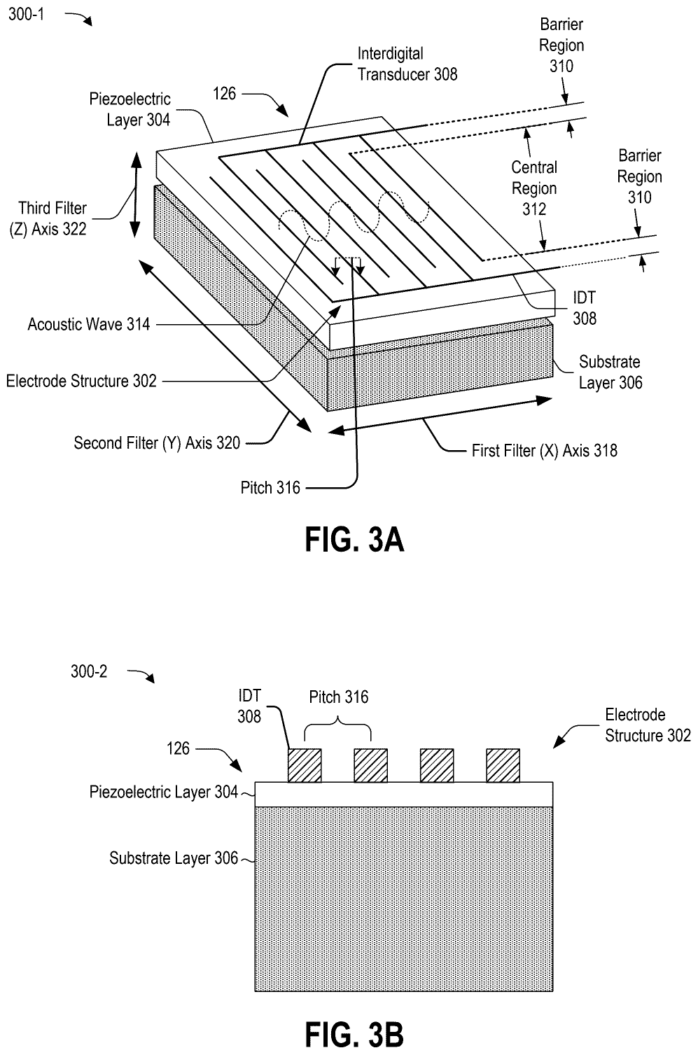

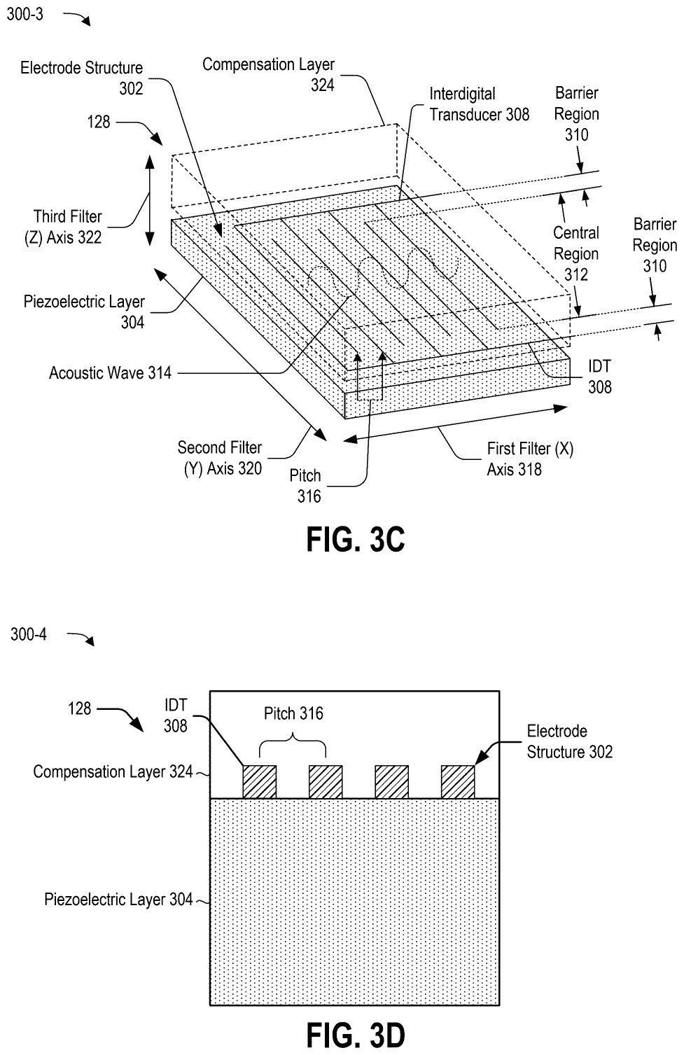

FIGS. 3A and 3B illustrate an example implementation of the thin-film surface-acoustic-wave filter 126 with site-selective piezoelectric-layer trimming. A three-dimensional perspective view 300-1 of the thin-film surface-acoustic-wave filter 126 is shown in FIG. 3A, and a two-dimensional cross-section view 300-2 of the thin-film surface-acoustic-wave filter 126 is shown in FIG. 3B.

The thin-film surface-acoustic-wave filter 126 includes at least one electrode structure 302, at least one piezoelectric layer 304 (e.g., piezoelectric material), and at least one substrate layer 306. The electrode structure 302 is implemented using conductive material, such as metal, and can include one or more layers. The one or more layers can include one or more metal layers and can optionally include one or more adhesion layers. As an example, the metal layers can be composed of aluminum (Al), copper (Cu), silver (Ag), gold (Au), tungsten (W), or some combination or doped version thereof. The adhesion layers can be composed of chromium (Cr), titanium (Ti), molybdenum (Mo), or some combination thereof.

The electrode structure 302 can include one or more interdigital transducers 308. The interdigital transducer 308 converts an electrical signal into an acoustic wave and converts the acoustic wave into a filtered electrical signal. Although not explicitly shown, the electrode structure 302 can also include two or more reflectors. In an example implementation, the interdigital transducer 308 is arranged between two reflectors (not shown), which reflect the acoustic wave back towards the interdigital transducer 308.

In the depicted configuration shown in the two-dimensional cross-section view 300-2, the piezoelectric layer 304 is disposed between the electrode structure 302 and the substrate layer 306. The piezoelectric layer 304 can be implemented using a variety of different materials that exhibit piezoelectric properties (e.g., can transfer mechanical energy into electrical energy or electrical energy into mechanical energy). Example types of material include lithium niobate (LiNbO₃), lithium tantalate (LiTaO₃), or quartz. In general, the material that forms the piezoelectric layer 304 has a crystalline structure. This crystalline structure is defined by an ordered arrangement of particles (e.g., atoms, ions, or molecules).

The substrate layer 306 includes one or more sublayers that can support passivation, temperature compensation, power handling, mode suppression, and so forth. As an example, the substrate layer 306 can include at least one compensation layer, at least one charge-trapping layer, at least one support layer, or some combination thereof. These sublayers can be considered part of the substrate layer 306 or their own separate layers. Example types of material that can form one or more sublayers within the substrate layer 306 include silicon dioxide (SiO₂), polysilicon (poly-Si) (e.g., polycrystalline silicon or multicrystalline silicon), amorphous silicon, silicon nitride (SiN), silicon oxynitride (SiON), aluminum nitride (AlN), non-conducting material (e.g., silicon (Si), doped silicon, sapphire, silicon carbide (SiC), fused silica, glass, diamond), or some combination thereof.

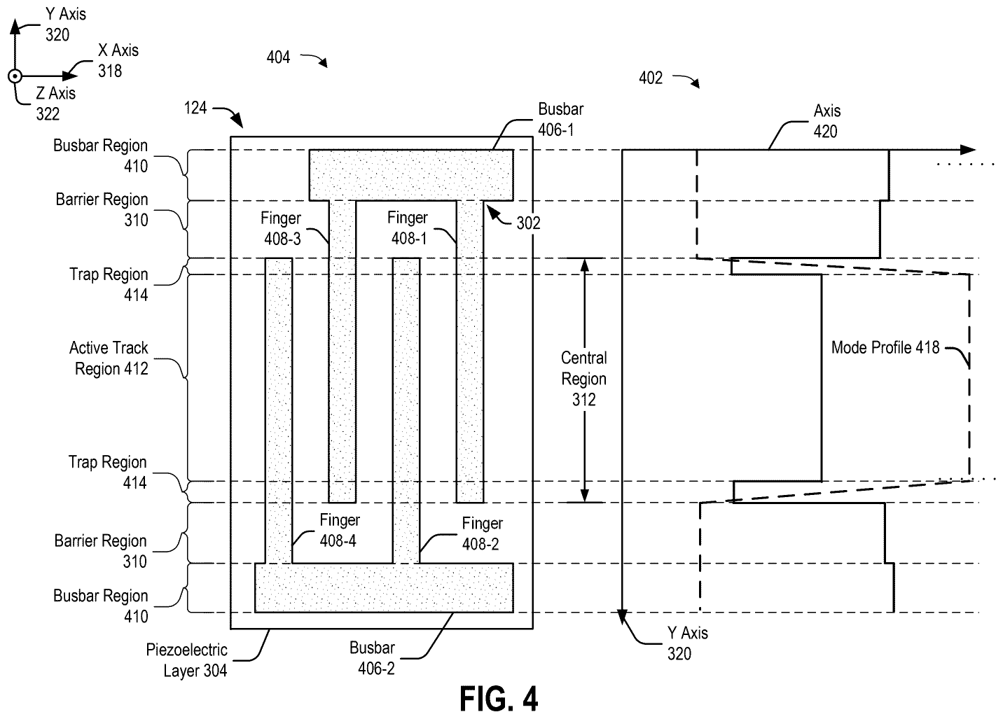

In the three-dimensional perspective view 300-1, the interdigital transducer 308 is shown to have two comb-shaped electrode structures with fingers (e.g., electrode fingers) extending from two busbars (e.g., conductive segments or rails) towards each other in an interleaved fashion (e.g., interleaved electrode fingers. The fingers are arranged in an interlocking or interleaved manner in between the two busbars of the interdigital transducer 308 (e.g., arranged in an interdigitated manner). In other words, the fingers connected to a first busbar extend towards a second busbar but do not connect to the second busbar. As such, there is a barrier region 310 between the ends of these fingers and the second busbar. Likewise, fingers connected to the second busbar extend towards the first busbar but do not connect to the first busbar. There is therefore a barrier region 310 between the ends of these fingers and the first busbar, as further described with respect to FIG. 4.

In the direction along the busbars, there is an overlap region including a central region 312 where a portion of one finger overlaps with a portion of an adjacent finger. This central region 312, including the overlap, may be referred to as the aperture, track, or active region where electric fields are produced between fingers to cause an acoustic wave 314 to form at least in this region of the piezoelectric layer 304.

A physical periodicity of the fingers is referred to as a pitch 316 of the interdigital transducer 308. The pitch 316 may be indicated in various ways. For example, in certain aspects, the pitch 316 may correspond to a magnitude of a distance between consecutive fingers of the interdigital transducer 308 in the central region 312. This distance may be defined, for example, as the distance between the center points of each of the fingers. The distance may be generally measured between the right (or left) edge of one finger and the right (or left) edge of an adjacent finger when the fingers have uniform widths. In certain aspects, an average of distances between adjacent fingers of the interdigital transducer 308 may be used for the pitch 316. The frequency at which the piezoelectric layer 304 vibrates is a main-resonance frequency of the electrode structure 302. The frequency is determined at least in part by the pitch 316 of the interdigital transducer 308 and other properties of the thin-film surface-acoustic-wave filter 126.

It should be appreciated that while a certain number of fingers are illustrated in FIGS. 3A-D, the number of actual fingers and lengths and width of the fingers and busbars may be different in an actual implementation. Such parameters depend on the particular application and desired filter characteristics. In addition, the thin-film surface-acoustic-wave filter 126 can include multiple interconnected electrode structures each including multiple interdigital transducers 308 to achieve a desired passband (e.g., multiple interconnected resonators or interdigital transducers 308 in series or parallel connections to form a desired filter transfer function).

Although not shown, each reflector within the electrode structure 302 can have two busbars and a grating structure of conductive fingers that each connect to both busbars. In some implementations, the pitch of the reflector can be similar to or the same as the pitch 316 of the interdigital transducer 308 to reflect the acoustic wave 314 in the resonant frequency range.

In the three-dimensional perspective view 300-1, the thin-film surface-acoustic-wave filter 126 is defined by a first (X) axis 318, a second (Y) axis 320, and a third (Z) axis 322. The first axis 318 and the second axis 320 are parallel to a planar surface of the piezoelectric layer 304, and the second axis 320 is perpendicular to the first axis 318. The third axis 322 is normal (e.g., perpendicular) to the planar surface of the piezoelectric layer 304. The busbars of the interdigital transducer 308 are oriented to be parallel to the first axis 318. The fingers of the interdigital transducer 308 are orientated to be parallel to the second axis 320. Also, an orientation of the piezoelectric layer 304 causes an acoustic wave 314 to mainly form in a direction of the first axis 318. As such, the acoustic wave 314 forms in a direction that is substantially perpendicular to the direction of the fingers of the interdigital transducer 308. Another example type of surface-acoustic-wave filter 124 is further described with respect to FIGS. 3C and 3D.

FIGS. 3C and 3D illustrate an example implementation of the high-quality temperature-compensated surface-acoustic-wave filter 128 with site-selective piezoelectric-layer trimming. A three-dimensional perspective view 300-3 of the high-quality temperature-compensated surface-acoustic-wave filter 128 is shown in FIG. 3C, and a two-dimensional cross-section view 300-4 of the high-quality temperature-compensated surface-acoustic-wave filter 128 is shown in FIG. 3D.

The high-quality temperature-compensated surface-acoustic-wave filter 128 includes at least one electrode structure 302, at least one piezoelectric layer 304, and at least one compensation layer 324. The compensation layer 324 can provide temperature compensation to enable the high-quality temperature-compensated surface-acoustic-wave filter 128 to achieve a target temperature coefficient of frequency. In example implementations, the compensation layer 324 can be implemented using at least one silicon dioxide layer.

In the depicted configuration shown in the two-dimensional cross-section view 300-4, the electrode structure 302 is disposed between the piezoelectric layer 304 and the compensation layer 324. The piezoelectric layer 304 can form a substrate of the high-quality temperature-compensated surface-acoustic-wave filter 128.

The electrode structure 302 of the high-quality temperature-compensated surface-acoustic-wave filter 128 can be similar to the electrode structure 302 described above with respect to the thin-film surface-acoustic-wave filter 126 of FIG. 3-1. Likewise, the piezoelectric layer 304 of the high-quality temperature-compensated surface-acoustic-wave filter 128 can be similar to the piezoelectric layer 304 described above with respect to the thin-film surface-acoustic-wave filter 126 of FIG. 3-1. The piezoelectric layer 304 of the high-quality temperature-compensated surface-acoustic-wave filter 128, however, can be thicker than the piezoelectric layer 304 of the thin-film surface-acoustic-wave filter 126 of FIGS. 3A and 3B.

In the three-dimensional perspective view 300-1, the high-quality temperature-compensated surface-acoustic-wave filter 128 is defined by the first (X) axis 318, the second (Y) axis 320, and the third (Z) axis 322. The first axis 318 and the second axis 320 are parallel to a planar surface of the piezoelectric layer 304, and the second axis 320 is perpendicular to the first axis 318. The third axis 322 is normal (e.g., perpendicular) to the planar surface of the piezoelectric layer 304. The busbars of the interdigital transducer 308 are oriented to be parallel to the first axis 318. The fingers of the interdigital transducer 308 are orientated to be parallel to the second axis 320. Also, an orientation of the piezoelectric layer 304 causes an acoustic wave 314 to mainly form in a direction of the first axis 318. As such, the acoustic wave 314 forms in a direction that is substantially perpendicular to the direction of the fingers of the interdigital transducer 308.

Similar to the thin-film surface-acoustic-wave filter 126 of FIGS. 3A and 3B, the high-quality temperature-compensated surface-acoustic-wave filter 128 of FIGS. 3C and 3D can also include the barrier region 310 and the central region 312. The thin-film surface-acoustic-wave filter 126 and the high-quality temperature-compensated surface-acoustic-wave filter 128 can have similar operations, which are generally described below with respect to the surface-acoustic-wave filter 124.

During operation, the surface-acoustic-wave filter 124 (e.g., the thin-film surface-acoustic-wave filter 126 or the high-quality temperature-compensated surface-acoustic-wave filter 128) accepts a radio-frequency signal, such as the pre-filter transmit signal 224 or the pre-filter receive signal 230 shown in FIG. 2. The electrode structure 302 excites an acoustic wave 314 on the piezoelectric layer 304 using the inverse piezoelectric effect. For example, the interdigital transducer 308 in the electrode structure 302 generates an alternating electric field based on the accepted radio-frequency signal. The piezoelectric layer 304 enables the acoustic wave 314 to be formed in response to the alternating electric field generated by the interdigital transducer 308. In other words, the piezoelectric layer 304 causes, at least partially, the acoustic wave 314 to form responsive to electrical stimulation by one or more interdigital transducers 308.

The acoustic wave 314 propagates across the piezoelectric layer 304 and interacts with the interdigital transducer 308 or another interdigital transducer within the electrode structure 302 (not shown in FIGS. 3A-D). The acoustic wave 314 that propagates can be a standing wave. In some implementations, two reflectors within the electrode structure 302 cause the acoustic wave 314 to be formed as a standing wave across a portion of the piezoelectric layer 304. In other implementations, the acoustic wave 314 propagates across the piezoelectric layer 304 from the interdigital transducer 308 to another interdigital transducer (not shown).

Using the piezoelectric effect, the electrode structure 302 generates a filtered radio-frequency signal based on the propagated surface acoustic wave 314. In particular, the piezoelectric layer 304 generates an alternating electric field due to the mechanical stress generated by the propagation of the acoustic wave 314. The alternating electric field induces an alternating current in the other interdigital transducer or the interdigital transducer 308. This alternating current forms the filtered radio-frequency signal, which is provided at an output of the surface-acoustic-wave filter 124. The filtered radio-frequency signal can include the filtered transmit signal 226 or the filtered receive signal 232 of FIG. 2.

FIG. 4 illustrates an example graph 402 depicting velocity and mode profiles associated with regions of the surface-acoustic-wave filter 124 with site-selective piezoelectric-layer trimming. The surface-acoustic-wave filter 124 can be the thin-film surface-acoustic-wave filter 126 or the high-quality temperature-compensated surface-acoustic-wave filter 128. A two-dimensional top-down view 404 of the surface-acoustic-wave filter 124 is illustrated on the left side of FIG. 4. In the depicted configuration, the electrode structure 302 of the surface-acoustic-wave filter 124 includes a first busbar 406-1, a second busbar 406-2, and fingers 408-1, 408-2, 408-3, and 408-4. The fingers 408-1 and 408-3 are connected to the first busbar 406-1 and extend along the second (Y) axis 320 towards the second busbar 406-2 without connecting to the second busbar 406-2. The fingers 408-2 and 408-4 are connected to the second busbar 406-2 and extend along the second (Y) axis 320 towards the first busbar 406-1 without connecting to the first busbar 406-1.

The surface-acoustic-wave filter 124 includes multiple distinct regions along the second (Y) axis 320. These regions are defined, at least in part, based on a physical layout of the electrode structure 302. The regions include a busbar region 410, the barrier region 310, and the central region 312. The busbar region 410 includes the busbars 406-1 and 406-2 and extends across portions of the second (Y) axis 320 that correspond with the widths of the busbars 406-1 and 406-2. In this case, two busbar regions 410 are shown to be associated with the two busbars 406-1 and 406-2, respectively.

The barrier region 310 is present between the central region 312 and the busbar region 410. In particular, the barrier region 310 includes portions of the second (Y) axis 320 that extend between one busbar and the ends of fingers associated with another busbar (e.g., an opposite busbar). For example, a first barrier region 310 exists between the first busbar 406-1 and the ends of fingers 408-2 and 408-4, which are associated with the second busbar 406-2. A second barrier region 310 exists between the second busbar 406-2 and ends of fingers 408-1 and 408-3, which are associated with the first busbar 406-1.

The central region 312 is defined by the overlap of fingers 408-1 to 408-4 across the first (X) axis 318. As depicted in the top-down view 404, the central region 312 includes at least one active track region 412 and at least one trap region 414. The trap region 414 is present between the barrier region 310 and the active track region 412. In this way, the trap region 414 exists at the outer boundaries of the central region 312. In general, the main or fundamental mode of the surface-acoustic-wave filter 124 is designed to propagate within the active track region 412.

A width of the trap region 414 along the second (Y) axis 320 can be tailored to achieve a target performance. In an example implementation, the width of the trap region 414 is approximately equal to the pitch 316 (of FIG. 3-1 or 3-2) of the electrode structure 302. For example, the width of the trap region 414 and the pitch 316 can be approximately 1 micrometer (μm). For clarity, the regions of the surface-acoustic-wave filter 124 are not necessarily drawn to scale in the top-down view 404. Further, each region may have some variability that deviates from the illustrated proportions or widths, including due to the constraints of a given manufacturing technology. For example, the trap region 414 may extend beyond the ends of fingers over which the trap region 414 is disposed.

With the implementation of site-selective piezoelectric-layer trimming, structural characteristics of the piezoelectric layer 304 within the trap region 414 can vary from the other regions, including the active track region 412. This variation causes the acoustic wave 314 (of FIG. 3-1 or 3-2) to have a lower velocity (e.g., a lower transversal velocity) than within the active track region 412, as seen by a graph 402 illustrated on the right of FIG. 4.

The graph 402 depicts a velocity profile 416 and a mode profile 418 across the second (Y) axis 320 and a horizontal axis 420. The velocity profile 416 is illustrated using a solid line, and the mode profile 418 is illustrated using a dashed line. The horizontal axis 420 represents velocity (e.g., velocity of the acoustic wave 314) for the velocity profile 416 and amplitude for the mode profile 418. Using site-selective piezoelectric-layer trimming, the velocity profile 416 can be designed to reduce (suppress) spurious transversal modes and promote excitation of the main or fundamental wave mode.

The velocity profile 416 indicates velocities (e.g., wave velocities) of each region of the surface-acoustic-wave filter 124. As seen in the graph 402, the velocity of the acoustic wave 314 is higher within the busbar region 410 and the barrier region 310 in comparison to the central region 312. In general, the acoustic wave 314 can readily propagate in regions in which the velocity is lower, such as within the central region 312. The relatively higher velocity within the barrier region 310 and the busbar region 410 effectively forms a barrier, which isolates the central region 312 and reduces leakage (e.g., loss) within the surface-acoustic-wave filter 124.

Within the central region 312, the velocity is lower within the trap region 414 in comparison to the active track region 412. The lower velocity within the trap region 414 can shape the transversal profile (e.g., amplitude) of the fundamental mode, which is depicted by the mode profile 418. As an example, a difference in velocities between the active track region 412 and the trap region 414 can be on the order of tens of meters per second (m/s). In an example implementation, the difference in velocities is between approximately 30 and 40 m/s.

The mode profile 418 indicates the amplitude of the fundamental wave mode across the different regions. In this example, the mode profile 418 has a rectangular or pulse shape, which corresponds to a piston mode in which spurious transversal modes are substantially suppressed (e.g., attenuated). The piston mode is characterized by the amplitude being generally flat (e.g., the same) across the active track region 412 and higher within the active track region 412 in comparison to the busbar region 410 and the barrier region 310.

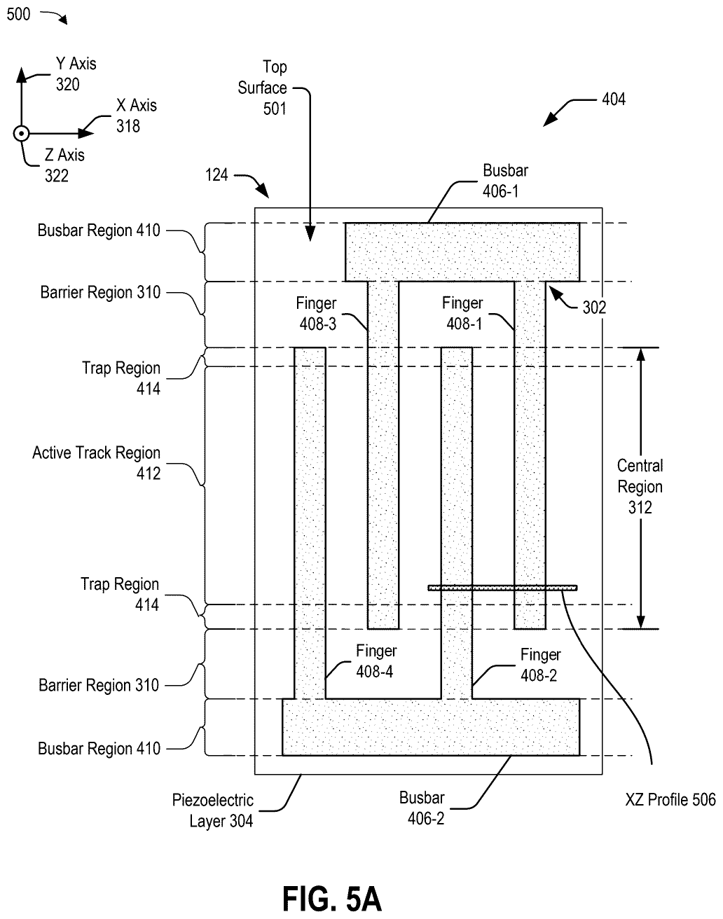

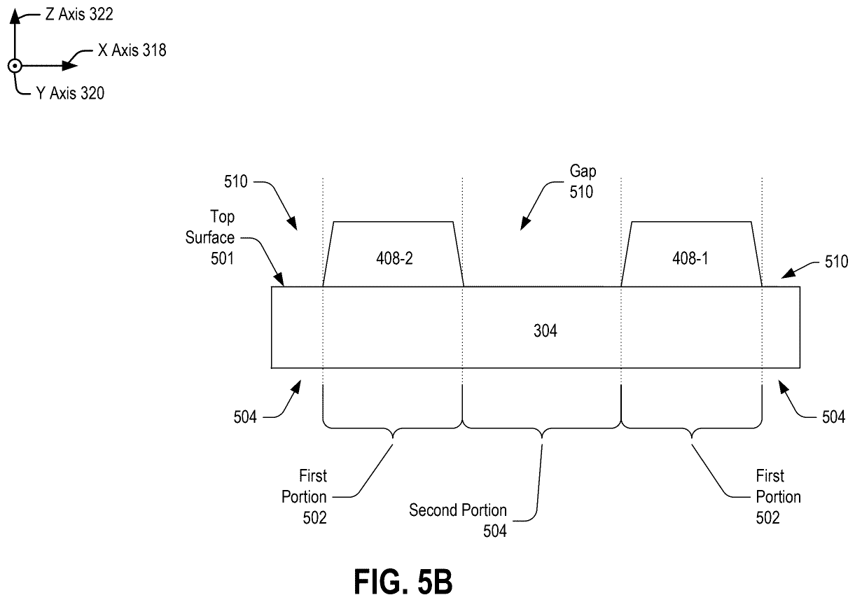

FIG. 5A illustrates aspects of the surface-acoustic-wave filter 124 with geometry tuning in accordance with aspects described herein. Similar to FIG. 4, FIG. 5A illustrates a two-dimensional top-down view 404 of the surface-acoustic-wave filter 124. Further, as illustrated, the filter 124 includes a top surface of the piezoelectric layer, which will be covered by a dielectric layer that also covers the metallization layer used for the busbars 406-2 and 4-6-2, and the fingers 408-1 through 408-4. In the depicted configuration, the electrode structure 302 has a comb shape. Due to this comb shape, the fingers 408-1 to 408-4 are distributed across the first (X) axis 318 and have lengths along the second (Y) axis 320. This distribution causes consecutive pairs of fingers 408-1 to 408-4 to be separated across the first (X) axis 318. This separation forms gaps (e.g., openings) within the electrode structure 302. Such gaps are illustrated by XZ profile section 506, which is detailed further in FIG. 5B.

FIG. 5B illustrates aspects of the surface-acoustic-wave filter 124 with geometry tuning in accordance with aspects described herein. Within the central region 312 of FIG. 5A, there are gaps 510 between fingers 408-1 and 408-2, between fingers 408-2 and 408-3, and between fingers 408-3 and 408-4. The electrode structure 302 can also be considered to have gaps to the left of the finger 408-4 (as depicted in FIG. 5A) and to the right of the finger 408-1. The electrode structure 302 can further be considered to have gaps within the barrier region 310 and across portions of the busbar region 410 that are not occupied by the busbars 406-1 and 406-2.

FIG. 5B provides a detailed cross-section in the XZ profile section 506, which illustrates fingers 408-1 and 408-2, with gaps 510 between the fingers and on each side of the fingers 408-1 and 408-2. Different portions of the piezoelectric layer 304 can be defined with respect to the electrode structure 302. A first portion 502 of the piezoelectric layer 304 is covered by the electrode structure 302. This first portion 502 (e.g., a covered portion) supports (e.g., physically supports) the electrode structure 302 and is positioned directly below (as shown in FIG. 5A) the electrode structure 302 along the third (Z) axis 322. In the two-dimensional top-down view 404 of the surface-acoustic-wave filter 124, the first portion 502 is not visible as it is underneath the electrode structure 302.

A second portion 504 of the piezoelectric layer 304 is exposed by the gaps within the electrode structure 302. The second portion 504 (e.g., an exposed portion) does not support (e.g., is not physically in direct contact with) the electrode structure 302 and is not positioned directly below the electrode structure 302. Within the central region 312, the second portion 504 exists between consecutive pairs of fingers 408-1 to 408-4. The second portion 504 also exists to the left of finger 408-4 and to the right of the finger 408-1. In the two-dimensional top-down view 404 of the surface-acoustic-wave filter 124, the second portion 504 of the piezoelectric layer 304 includes the surface of the piezoelectric layer 304 that is visible and not “hidden” by the electrode structure 302. The first portion 502 and the second portion 504 are also depicted in XZ profile section 506 of the surface-acoustic-wave filter 124.

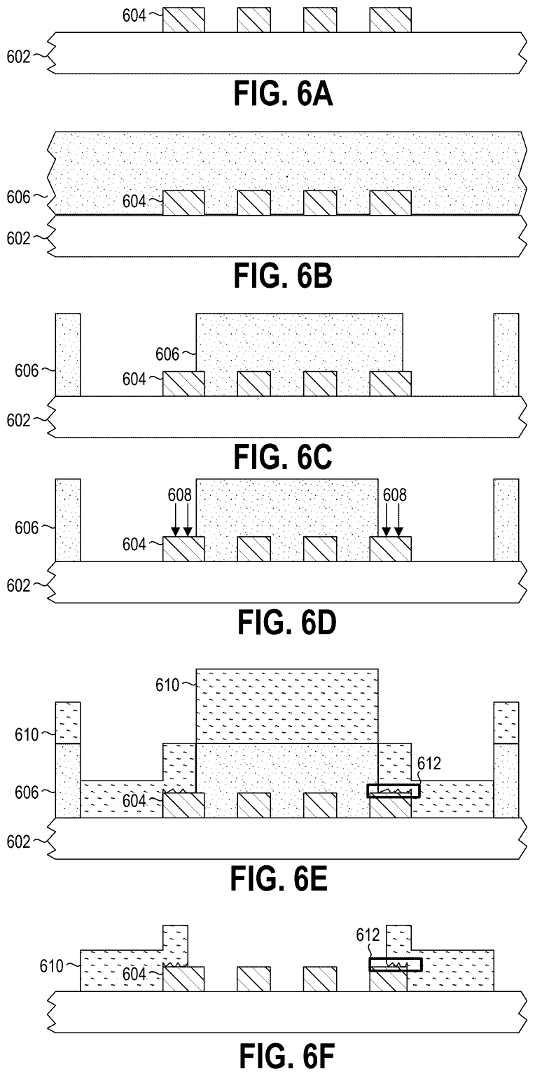

FIGS. 6A-6F illustrate a process of manufacturing a piezoelectric device based on etching between an interconnect and an electrode. Etching creates a rough surface and creates a poor ohmic contact between an interconnect and an electrode. The poor ohmic contact increases contact loss and decreases the yield of a piezoelectric device manufacturing process.

FIG. 6A illustrates that substrate 602 is metallized with a conductive layer 604 using a metallization process (e.g. using a chemical vapor deposition, sputtering, electroplating, or other process). For example, the conductive layer 604 may be aluminum or copper and may form an electrode of a piezoelectric device. A piezoelectric layer can also be formed on the substrate 602 and is omitted from the illustration for clarity of explanation.

After the conductive layer is deposited or formed, a resist layer 606 is applied over the conductive layer 604. For example, FIG. 6B illustrates that the resist layer 606 is formed on the entire substrate 602. FIG. 6C illustrates that a portion of the resist layer 606 is removed to expose a portion of the conductive layer 604.

An etchant 608 is applied to the exposed portion of the conductive layer 604 to remove oxidation as shown in FIG. 6D. In some aspects, etchant produces a rough surface when removing oxidation due to the uneven nature of the chemical reactions. For example, different areas of an oxidized surface may react at different rates with the etchant due to differences in the thickness of the oxide layer, the composition of the oxide, or the presence of impurities or defects. An etchant may also attack grain boundaries, dislocations, and defects in the oxide layer more aggressively than the bulk material, creating uneven and rough surfaces. In some cases, the etchant may not be uniform in composition or structure areas might be more chemically reactive than others, leading to selective etching and a rougher surface. In addition, oxidation may also be uneven and microstructures can also affect etching rates.

After etching, an interconnect layer 610 is formed (e.g., chemical vapor deposition, sputtering, etc.) over the substrate as shown in FIG. 6E. A contact region 612 is formed between the interconnect layer 610 and the conductive layer 604 with a rough surface as a result of the rough surface created by the etching process in FIG. 6D. For example, microgaps and other structural defects can be created at the interface between the interconnect layer 610 and the conductive layer 604 during the etching.

Portions of the interconnect layer 610 are removed to expose electrodes formed by the conductive layer 604 as shown in FIG. 6F. However, the electrodes may have poor electrical contact with the piezoelectric device based on the rough surface of the contact region 612. For example, the interface between the electrodes and the interconnect 610 increases insertion loss, particularly for low-loss requirements for applications such as an RF receiver.

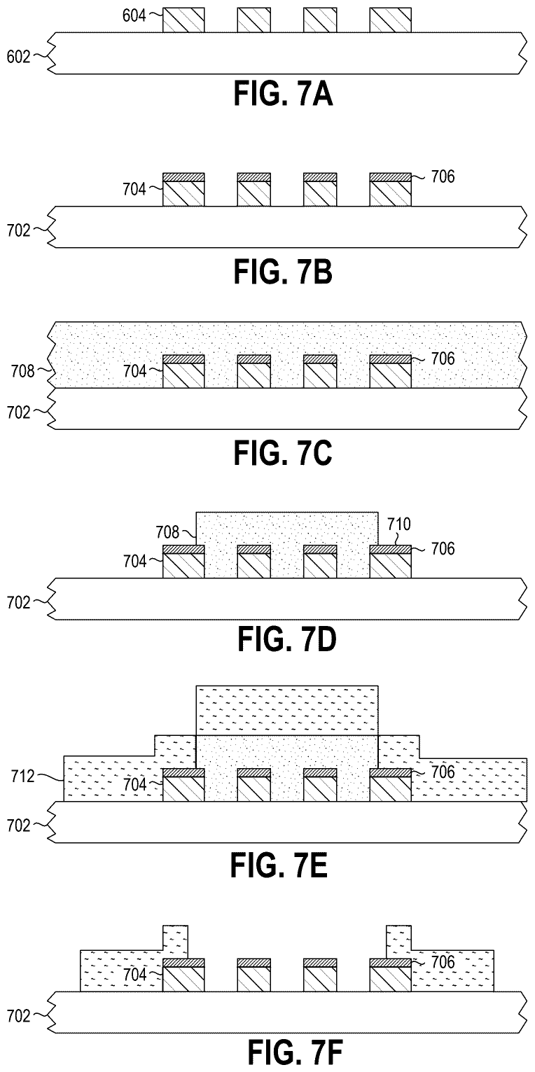

FIGS. 7A-7F illustrate a process of manufacturing a piezoelectric device in accordance with some aspects of the disclosure. In some aspects, FIG. 7A illustrates a substrate 702 is metalized with a conductive layer 704 using a metallization process (e.g. using a chemical vapor deposition, sputtering, electroplating, or other process). The conductive layer 704 may be aluminum or copper and may form an electrode of a piezoelectric device. A piezoelectric layer can also be formed on the substrate 702 and is omitted from the illustration for clarity of explanation.

After a metallization process forms the conductive layer 704, a conductive protective layer 706 is formed over the conductive layer 704 as shown in FIG. 7B. In some aspects, the conductive protective layer 706 is a different material than a conventional electrode and has a stable ion structure that forms a thin, stable oxide layer that stops further oxidation. For example, the conductive protective layer 706 may be chromium or titanium. Chromium readily reacts with oxygen to form a thin, stable layer of chromium oxide (Cr₂O₃) that effectively seals the surface and prevents further oxidation under the chromium oxide. For example, a chromium oxide can be formed having a thickness of less than 1 nanometer (nm) and can provide a conformal and closed layer (e.g., is consistent across the entire surface). Chromium oxide is stable, consistent, and smooth, providing a reliable contact surface. In some aspects, titanium also forms a stable and protective oxide layer of primarily titanium dioxide (TiO₂). Titanium dioxide has similar properties to chromium oxide and is highly adherent and protects the underlying titanium from further oxidation. Chromium and Titanium are also self-healing and quickly reform a protective layer in the event of any damage that may expose additional metal.

In some aspects, a thickness of the conductive protective layer 706 is selected to prevent ohmic losses. In some aspects, the conductive protective layer 706 comprises a thickness in the range of 1 nm to 5 nm. For example, chromium has an electrical resistance of 125 nΩ·m (nanoohm-meters) and titanium has an electrical resistance of 420 nΩ·m, whereas aluminum has an electrical resistance of 26.5 nΩ·m. In addition, a thickness of the conductive protective layer 706 is also selected based on electro-acoustical properties of the piezoelectric device. By adding mass (e.g., mass loading) to the electrode, electro-acoustical performance of the piezoelectric device can be affected and the conductive protective layer may have a higher mass (e.g., titanium has an atomic weight 47.867 g/mol, chromium has an atomic weight of 51.996 g/mol) than the electrode (e.g., alumni has an atomic weight of 26.98 g/mol). The conductive protective layer also forms a smoother surface and provides a consistent interface for an interconnect of the piezoelectric device to reduce ohmic losses.

After the conductive protective layer 706 is formed, a resist layer 708 is applied over the conductive protective layer 706 and the substrate 702 as shown in FIG. 7C. A portion of the resist layer 708 is then removed to expose an interface 710 for an interconnect layer as shown in FIG. 7D. For example, the conductive protective layer 706 may be exposed. In this case, the conductive protective layer 706 does not require etching to remove an inconsistent oxidation layer of the conductive layer 704.

An interconnect layer 712 is then formed over the conductive protective layer 706 as shown in FIG. 7E. After the interconnect layer 712 is formed, a portion of the interconnect layer 712 is removed (e.g., resist strip lift off) to expose electrodes of piezoelectric devices on the substrate 702 as shown in FIG. 7F.

Because the conductive protective layer 706 has a stable, thin, and smooth oxide layer that protects the conductive protective layer 706, the interface 710 provides a consistent and larger surface area for the interconnect layer 712 and ensures cohesion between the conductive protective layer 706 and the interconnect layer 712 while minimizing microgaps and other microstructures that can affect electrical performance. For example, the conductive protective layer 706 provides a more consistent interface and may reduce the standard deviation of insertion loss of all piezoelectric device on the substrate 702 by 0.05 dB. In some examples, the yield rate of piezoelectric devices on the substrate 702 increases by 2%. The process also excludes an etching step, which reduces processing costs and decreases process variation.

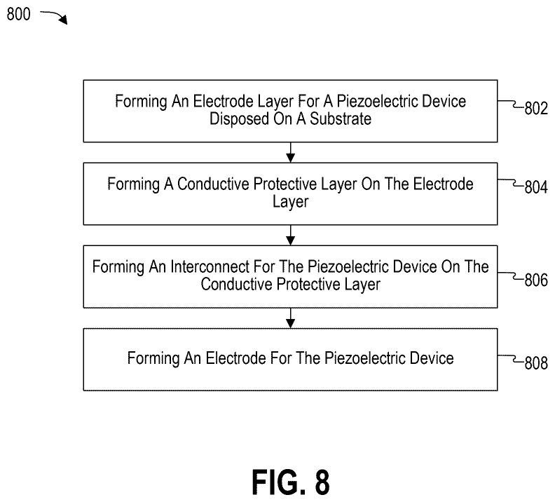

FIG. 8 is a flow diagram 800 illustrating an example process 800 for manufacturing a piezoelectric device such as a surface-acoustic-wave filter in accordance with aspects described herein. At block 802, the process includes forming an electrode layer for a piezoelectric device disposed on a substrate.

At block 804, the process includes forming a conductive protective layer on the electrode layer. In one aspect, the conductive protective layer comprises a stable oxide layer, which may provide a conformal and closed layer (e.g., is consistent across the entire surface). For example, the conductive protective layer comprises one of a chromium layer or a titanium layer, and a stable oxide layer being forms over the conductive protective layer. A thickness of the conductive protective layer may be associated with an electroacoustical property of the piezoelectric layer. For example, the thickness is configured to minimize mass while providing a stable bonding surface. Mass can affect electroacoustical properties and the thickness of the conductive protective layer may be between 1 to 5 nanometers to prevent effecting electroacoustical properties. A stable bonding surface increases bonding of the interconnect, reduces an insertion loss of the piezoelectric device, and reduces process deviation in manufacturing processes. For example, yield rate can increase by 2% in some cases.

At block 806, the process includes forming an interconnect for the piezoelectric device on the conductive protective layer. In one aspect, the process of forming the interconnect may include forming a resist layer on the substrate and the conductive protective layer, removing a portion of the resist layer to expose an interconnect region for the piezoelectric device, and forming an interconnect layer on the resist layer over the conductive protective layer and the interconnect region. In further detail, forming the electrode in this aspect can include removing a portion of the interconnect layer to create the electrode.

At block 808, the process includes forming an electrode for the piezoelectric device. In some aspects, the interconnect forms an electrical path from an exposed surface of the conductive protective layer to the piezoelectric device.

In some examples, the techniques or processes described herein may be performed by a computing device, an apparatus, and/or any other computing device. In some cases, the computing device or apparatus may include a processor, microprocessor, microcomputer, or other component of a device that is configured to carry out the steps of processes described herein. For example, the components can include and/or can be implemented using electronic circuits or other electronic hardware, which can include one or more programmable electronic circuits (e.g., microprocessors, graphics processing units (GPUs), digital signal processors (DSPs), central processing units (CPUs), and/or other suitable electronic circuits), and/or can include and/or be implemented using computer software, firmware, or any combination thereof, to perform the various operations described herein. The computing device may further include a display (as an example of the output device or in addition to the output device), a network interface configured to communicate and/or receive the data, any combination thereof, and/or other component(s). The network interface may be configured to communicate and/or receive Internet Protocol (IP) based data or other type of data.

The processes described herein can be implemented in hardware, computer instructions, or a combination thereof. In the context of computer instructions, the operations represent computer-executable instructions stored on one or more computer-readable storage media that, when executed by one or more processors, perform the recited operations. Generally, computer-executable instructions include routines, programs, objects, components, data structures, and the like that perform particular functions or implement particular data types. The order in which the operations are described is not intended to be construed as a limitation, and any number of the described operations can be combined in any order and/or in parallel to implement the processes.

The process 800 is illustrated as a logical flow diagram, the operations of which represent sequences of operations that can be implemented in hardware, computer instructions, or a combination thereof. In the context of computer instructions, the operations represent computer-executable instructions stored on one or more computer-readable storage media that, when executed by one or more processors, perform the recited operations. Generally, computer-executable instructions include routines, programs, objects, components, data structures, and the like that perform particular functions or implement particular data types. The order in which the operations are described is not intended to be construed as a limitation, and any number of the described operations can be combined in any order and/or in parallel to implement the processes.

Additionally, the processes described herein (e.g., the process 800 and/or other processes) may be performed under the control of one or more computer systems configured with executable instructions and may be implemented as code (e.g., executable instructions, one or more computer programs, or one or more applications) executing collectively on one or more processors, by hardware, or combinations thereof. As noted above, the code may be stored on a computer-readable or machine-readable storage medium, for example, in the form of a computer program including a plurality of instructions executable by one or more processors. The computer-readable or machine-readable storage medium may be non-transitory.

As used herein, the term “computer-readable medium” includes, but is not limited to, portable or non-portable storage devices, optical storage devices, and various other mediums capable of storing, containing, or carrying instruction(s) and/or data. A computer-readable medium may include a non-transitory medium in which data can be stored and that does not include carrier waves and/or transitory electronic signals propagating wirelessly or over wired connections. Examples of a non-transitory medium may include, but are not limited to, a magnetic disk or tape, optical storage media such as compact disk (CD) or digital versatile disk (DVD), flash memory, memory or memory devices. A computer-readable medium may have stored thereon code and/or machine-executable instructions that may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc. may be passed, forwarded, or transmitted using any suitable means including memory sharing, message passing, token passing, network transmission, or the like.

In some examples, the computer-readable storage devices, mediums, and memories can include a cable or wireless signal containing a bit stream and the like. However, when mentioned, non-transitory computer-readable storage media expressly exclude media such as energy, carrier signals, electromagnetic waves, and signals per se.

Specific details are provided in the description above to provide a thorough understanding of the examples provided herein. However, it will be understood by one of ordinary skill in the art that the examples may be practiced without these specific details. For clarity of explanation, in some instances the present technology may be presented as including individual functional blocks including functional blocks comprising devices, device components, steps or routines in a method embodied in software, or combinations of hardware and software. Additional components may be used other than those shown in the figures and/or described herein. For example, circuits, systems, networks, processes, and other components may be shown as components in block diagram form in order not to obscure the examples in unnecessary detail. In other instances, well-known circuits, processes, algorithms, structures, and techniques may be shown without unnecessary detail in order to avoid obscuring the examples.

Individual examples may be described above as a process or method which is depicted as a flowchart, a flow diagram, a data flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

Processes and methods according to the above-described examples can be implemented using computer-executable instructions that are stored or otherwise available from computer-readable media. Such instructions can include, for example, instructions and data which cause or otherwise configure a general purpose computer, special purpose computer, or a processing device to perform a certain function or group of functions. Portions of computer resources used can be accessible over a network. The computer executable instructions may be, for example, binaries, intermediate format instructions such as assembly language, firmware, source code, etc. Examples of computer-readable media that may be used to store instructions, information used, and/or information created during methods according to described examples include magnetic or optical disks, flash memory, USB devices provided with non-volatile memory, networked storage devices, and so on.

Devices implementing processes and methods according to these disclosures can include hardware, software, firmware, middleware, microcode, hardware description languages, or any combination thereof, and can take any of a variety of form factors. When implemented in software, firmware, middleware, or microcode, the program code or code segments to perform the necessary tasks (e.g., a computer-program product) may be stored in a computer-readable or machine-readable medium. A processor(s) may perform the necessary tasks. Typical examples of form factors include laptops, smart phones, mobile phones, tablet devices or other small form factor personal computers, personal digital assistants, rackmount devices, standalone devices, and so on. Functionality described herein also can be embodied in peripherals or add-in cards. Such functionality can also be implemented on a circuit board among different chips or different processes executing in a single device, by way of further example.

The instructions, media for conveying such instructions, computing resources for executing them, and other structures for supporting such computing resources are example means for providing the functions described in the disclosure.

In the foregoing description, aspects of the application are described with reference to specific examples thereof, but those skilled in the art will recognize that the application is not limited thereto. Thus, while illustrative examples of the application have been described in detail herein, it is to be understood that the inventive concepts may be otherwise variously embodied and employed, and that the appended claims are intended to be construed to include such variations, except as limited by the prior art. Various features and aspects of the above-described application may be used individually or jointly. Further, examples can be utilized in any number of environments and applications beyond those described herein without departing from the broader spirit and scope of the specification. The specification and drawings are, accordingly, to be regarded as illustrative rather than restrictive. For the purposes of illustration, methods were described in a particular order. It should be appreciated that in alternate examples, the methods may be performed in a different order than that described.

One of ordinary skill will appreciate that the less than (“<”) and greater than (“>”) symbols or terminology used herein can be replaced with less than or equal to (“s”) and greater than or equal to (“>”) symbols, respectively, without departing from the scope of this description.

Where components are described as being “configured to” perform certain operations, such configuration can be accomplished, for example, by designing electronic circuits or other hardware to perform the operation, by programming programmable electronic circuits (e.g., microprocessors, or other suitable electronic circuits) to perform the operation, or any combination thereof.

The phrase “coupled to” refers to any component that is physically connected to another component either directly or indirectly, and/or any component that is in communication with another component (e.g., connected to the other component over a wired or wireless connection, and/or other suitable communication interface) either directly or indirectly.

The term “substantially,” in reference to a given parameter, property, or condition, may refer to a degree that one of ordinary skill in the art would understand that the given parameter, property, or condition is met with a small degree of variance, such as, for example, within acceptable manufacturing tolerances. By way of example, depending on the particular parameter, property, or condition that is substantially met, the parameter, property, or condition may be at least 90% met, at least 95% met, or even at least 99% met.

Claim language or other language reciting “at least one of” a set and/or “one or more” of a set indicates that one member of the set or multiple members of the set (in any combination) satisfy the claim. For example, claim language reciting “at least one of A and B” or “at least one of A or B” means A, B, or A and B. In another example, claim language reciting “at least one of A, B, and C” or “at least one of A, B, or C” means A, B, C, or A and B, or A and C, or B and C, A and B and C, or any duplicate information or data (e.g., A and A, B and B, C and C, A and A and B, and so on), or any other ordering, duplication, or combination of A, B, and C. The language “at least one of” a set and/or “one or more” of a set does not limit the set to the items listed in the set. For example, claim language reciting “at least one of A and B” or “at least one of A or B” may mean A, B, or A and B, and may additionally include items not listed in the set of A and B. The phrases “at least one” and “one or more” are used interchangeably herein.

Claim language or other language reciting “at least one processor configured to,” “at least one processor being configured to,” “one or more processors configured to,” “one or more processors being configured to,” or the like indicates that one processor or multiple processors (in any combination) can perform the associated operation(s). For example, claim language reciting “at least one processor configured to: X, Y, and Z” means a single processor can be used to perform operations X, Y, and Z; or that multiple processors are each tasked with a certain subset of operations X, Y, and Z such that together the multiple processors perform X, Y, and Z; or that a group of multiple processors work together to perform operations X, Y, and Z. In another example, claim language reciting “at least one processor configured to: X, Y, and Z” can mean that any single processor may only perform at least a subset of operations X, Y, and Z.

Where reference is made to one or more elements performing functions (e.g., steps of a method), one element may perform all functions, or more than one element may collectively perform the functions. When more than one element collectively performs the functions, each function need not be performed by each of those elements (e.g., different functions may be performed by different elements) and/or each function need not be performed in whole by only one element (e.g., different elements may perform different sub-functions of a function). Similarly, where reference is made to one or more elements configured to cause another element (e.g., an apparatus) to perform functions, one element may be configured to cause the other element to perform all functions, or more than one element may collectively be configured to cause the other element to perform the functions.

Where reference is made to an entity (e.g., any entity or device described herein) performing functions or being configured to perform functions (e.g., steps of a method), the entity may be configured to cause one or more elements (individually or collectively) to perform the functions. The one or more components of the entity may include at least one memory, at least one processor, at least one communication interface, another component configured to perform one or more (or all) of the functions, and/or any combination thereof. Where reference to the entity performing functions, the entity may be configured to cause one component to perform all functions, or to cause more than one component to collectively perform the functions. When the entity is configured to cause more than one component to collectively perform the functions, each function need not be performed by each of those components (e.g., different functions may be performed by different components) and/or each function need not be performed in whole by only one component (e.g., different components may perform different sub-functions of a function).

The various illustrative logical blocks, modules, circuits, and algorithm steps described in connection with the examples disclosed herein may be implemented as electronic hardware, computer software, firmware, or combinations thereof. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present application.

The techniques described herein may also be implemented in electronic hardware, computer software, firmware, or any combination thereof. Such techniques may be implemented in any of a variety of devices such as general purposes computers, wireless communication device handsets, or integrated circuit devices having multiple uses including application in wireless communication device handsets and other devices. Any features described as modules or components may be implemented together in an integrated logic device or separately as discrete but interoperable logic devices. If implemented in software, the techniques may be realized at least in part by a computer-readable data storage medium comprising program code including instructions that, when executed, performs one or more of the methods described above. The computer-readable data storage medium may form part of a computer program product, which may include packaging materials. The computer-readable medium may comprise memory or data storage media, such as random access memory (RAM) such as synchronous dynamic random access memory (SDRAM), read-only memory (ROM), non-volatile random access memory (NVRAM), electrically erasable programmable read-only memory (EEPROM), FLASH memory, magnetic or optical data storage media, and the like. The techniques additionally, or alternatively, may be realized at least in part by a computer-readable communication medium that carries or communicates program code in the form of instructions or data structures and that can be accessed, read, and/or executed by a computer, such as propagated signals or waves.

The program code may be executed by a processor, which may include one or more processors, such as one or more digital signal processors (DSPs), general purpose microprocessors, an application specific integrated circuits (ASICs), field programmable logic arrays (FPGAs), or other equivalent integrated or discrete logic circuitry. Such a processor may be configured to perform any of the techniques described in this disclosure. A general purpose processor may be a microprocessor; but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. Accordingly, the term “processor,” as used herein may refer to any of the foregoing structure, any combination of the foregoing structure, or any other structure or apparatus suitable for implementation of the techniques described herein. In addition, in some aspects, the functionality described herein may be provided within dedicated software modules or hardware modules configured for encoding and decoding, or incorporated in a combined video encoder-decoder (CODEC).

Illustrative aspects of the present disclosure include:

Aspect 1: A piezoelectric device, comprising: a substrate; a piezoelectric layer; an electrode formed on the substrate, the electrode including a conductive layer and a conductive protective layer that is different from the conductive layer; and an interconnect formed on the piezoelectric layer over the conductive protective layer of the electrode, the interconnect providing an electrical path from the electrode to the piezoelectric layer.

Aspect 2: The piezoelectric device of Aspect 1, wherein the conductive protective layer comprises a stable oxide layer.

Aspect 3: The piezoelectric device of Aspect 2, wherein the conductive protective layer comprises one of a chromium layer or a titanium layer.

Aspect 4: The piezoelectric device of any of Aspects 2 to 3, wherein a thickness of the conductive protective layer is associated with an electroacoustical property of the piezoelectric layer.

Aspect 5: The piezoelectric device of Aspect 4, wherein the thickness is between 1 to 5 nanometers.

Aspect 6: The piezoelectric device of any of Aspects 1 to 5, wherein the conductive protective layer reduces an insertion loss of the piezoelectric device.

Aspect 7: The piezoelectric device of any of Aspects 1 to 6, wherein the conductive protective layer is bonded to a surface of a device incorporating the piezoelectric device.

Aspect 8: The piezoelectric device of any of Aspects 1 to 7, further comprising: a first interdigital transducer disposed over the piezoelectric layer; and a second interdigital transducer disposed over the piezoelectric layer; wherein the first interdigital transducer or the second interdigital transducer is coupled to the electrode; and wherein the first interdigital transducer, the second interdigital transducer, and the piezoelectric layer are configured to filter a signal provided to the electrode.

Aspect 9. A method of manufacturing a piezoelectric device, comprising: forming an electrode layer for a piezoelectric device disposed on a substrate; forming a conductive protective layer on the electrode layer; forming an interconnect for the piezoelectric device on the conductive protective layer; and forming an electrode for the piezoelectric device, wherein the interconnect forms an electrical path from an exposed surface of the conductive protective layer to the piezoelectric device.

Aspect 10: The method of Aspect 9, wherein forming the interconnect for the piezoelectric device comprises: forming a resist layer on the substrate and the conductive protective layer; removing a portion of the resist layer to expose an interconnect region for the piezoelectric device; forming an interconnect layer on the resist layer over the conductive protective layer and the interconnect region.

Aspect 11: The method of Aspect 10, wherein forming the electrode for the piezoelectric device comprises: removing a portion of the interconnect layer to create the electrode.

Aspect 12: The method of any of Aspects 10 to 11, wherein the conductive protective layer comprises a stable oxide layer.

Aspect 13: The method of any of Aspects 10 to 12, wherein the conductive protective layer comprises one of a chromium layer or a titanium layer.

Aspect 14: The method of Aspect 13, wherein a thickness of the conductive protective layer is associated with an electroacoustical property of the piezoelectric layer.

Aspect 15: The method of Aspect 14, wherein the thickness is between 1 to 5 nanometers.

Aspect 16: The method of any of Aspects 11 to 15, wherein the conductive protective layer reduces an insertion loss of the piezoelectric device.

Aspect 17: The method of any of Aspects 11 to 16, wherein the conductive protective layer is bonded to a surface of a device incorporating the piezoelectric device.

Aspect 18: A non-transitory computer-readable medium having stored thereon instructions that, when executed by at least one processor, cause the at least one processor to perform operations according to any of Aspects 9 to 17.

Aspect 19: An apparatus for performing a function, comprising one or more means for performing operations according to any of Aspects 9 to 17.

What is claimed is:

1. A piezoelectric device, comprising:
a substrate;
a piezoelectric layer;
an electrode formed on the substrate, the electrode including a conductive layer and a conductive protective layer that is different from the conductive layer; and
an interconnect formed on the piezoelectric layer over the conductive protective layer of the electrode, the interconnect providing an electrical path from the electrode to the piezoelectric layer.

2. The piezoelectric device of claim 1, wherein the conductive protective layer comprises a stable oxide layer.

3. The piezoelectric device of claim 2, wherein the conductive protective layer comprises one of a chromium layer or a titanium layer.

4. The piezoelectric device of claim 2, wherein a thickness of the conductive protective layer is associated with an electroacoustical property of the piezoelectric layer.

5. The piezoelectric device of claim 4, wherein the thickness is between 1 to 5 nanometers.

6. The piezoelectric device of claim 1, wherein the conductive protective layer reduces an insertion loss of the piezoelectric device.

7. The piezoelectric device of claim 1, wherein the conductive protective layer is bonded to a surface of a device incorporating the piezoelectric device.

8. The piezoelectric device of claim 1, further comprising:
a first interdigital transducer disposed over the piezoelectric layer; and
a second interdigital transducer disposed over the piezoelectric layer;
wherein the first interdigital transducer or the second interdigital transducer is coupled to the electrode; and
wherein the first interdigital transducer, the second interdigital transducer, and the piezoelectric layer are configured to filter a signal provided to the electrode.

9. A method of manufacturing a conductive protective layer, comprising:
forming an electrode layer for a piezoelectric device disposed on a substrate;
forming a conductive protective layer on the electrode layer;
forming an interconnect for the piezoelectric device on the conductive protective layer; and
forming an electrode for the piezoelectric device, wherein the interconnect forms an electrical path from an exposed surface of the conductive protective layer to the piezoelectric device.

10. The method of claim 9, wherein forming the interconnect for the piezoelectric device comprises:
forming a resist layer on the substrate and the conductive protective layer;
removing a portion of the resist layer to expose an interconnect region for the piezoelectric device; and
forming an interconnect layer on the resist layer over the conductive protective layer and the interconnect region.

11. The method of claim 10, wherein forming the electrode for the piezoelectric device comprises:
removing a portion of the interconnect layer to create the electrode.

12. The method of claim 10, wherein the conductive protective layer comprises a stable oxide layer.

13. The method of claim 10, wherein the conductive protective layer comprises one of a chromium layer or a titanium layer.

14. The method of claim 13, wherein a thickness of the conductive protective layer is associated with an electroacoustical property of a piezoelectric layer of the piezoelectric device.

15. The method of claim 14, wherein the thickness is between 1 to 5 nanometers.

16. The method of claim 11, wherein the conductive protective layer reduces an insertion loss of the piezoelectric device.

17. The method of claim 11, wherein the conductive protective layer is bonded to a surface of a device incorporating the piezoelectric device.
